(19) United States
(12) Patent Application Publication
(10) Pub. No.: US 2017/0227179 A1
(43) Pub. Date: Aug. 10, 2017

(54) Support structure for light radiation sources, corresponding device and method

(71) Applicant: OSRAM GmbH, Munich (DE)

(72) Inventors: Alessandro Scordino, Dolo (IT); Geert van der Meer, Ismaning (DE); Luca Volpato, Preganziol (IT)

(21) Appl. No.: 15/415,947

(22) Filed: Jan. 26, 2017

(30) Foreign Application Priority Data
Feb. 8, 2016 (IT) 102016000012659

(51) Int. Cl. F21S 4/24; F21V 29/503; F21K 9/90; H01L 25/075; H01L 33/64

(52) U.S. Cl. CPC F21S 4/24; H01L 25/0753; H01L 33/641; H01L 33/642; F21K 9/90; F21V 29/503; F21Y 2115/10

(57) ABSTRACT

A support structure for electrically-powered light radiation sources, e.g. LED sources, includes a ribbon-like flexible substrate with a front surface having, distributed therealong, mounting locations for light radiation sources. The ribbon-like substrate has a back surface with a plurality of thermally dissipative elements coupled to said back surface at locations opposed mounting locations of the light radiation sources on the front surface.

### CROSS-REFERENCE TO RELATED APPLICATION

This application claims priority to Italian Patent Application Serial No. 102016000012659, which was filed Feb. 8, 2016, and is incorporated herein by reference in its entirety.

### TECHNICAL FIELD

Various embodiments relate generally to lighting devices.

One or more embodiments may refer to lighting devices employing electrically-powered light radiation sources such as solid-state sources, e.g. LED sources.

### BACKGROUND

Lighting devices including an elongate, e.g. ribbon-like, and flexible support, whereon light radiation sources such as LED sources are mounted, may offer a high degree of installation flexibility. Users (installers and possibly final users) may cut strings of proper length from a continuous reel.

This procedure may however involve power limitations of the lighting sources, due to the heat generated by the latter in operation, to the requirements of the mounting surface (for example, wood or flammable materials must be avoided) or to the need of employing dedicated mounting profiles having thermally dissipative properties.

For example, in order to avoid exceeding temperature safety limits, LED modules adapted to be cut to a desired length and to be used in power applications may require being mounted on thermally dissipative surfaces.

In the case of mounting on non-dissipative surfaces (e.g. wood, plastic materials, certain kinds of drywalls), mounting profiles having thermal dissipation properties may be resorted to. Such profiles may however impose limitations due to their rigidity; this may reduce the benefits deriving from the flexibility of the lighting module itself.

Moreover, such modules may be destined to be applied onto the mounting surface and/or into the thermally dissipative profile by means of an adhesive tape. The latter may form an additional thermal interface which may further limit thermal dissipation from light radiation sources, e.g. LED sources. The possible use of thermally conductive adhesive tapes has the disadvantage of a rather high cost.

A further possible solution consists in using, as support surfaces for light radiation sources, semi-rigid elements similar to Printed Circuit Boards (PCBs) and made of materials such as Kapton or Aluminium. However, the drawback of this solution is the availability of such supports as single PCBs or panels, not as continuous reels which may be cut to length. This is an obvious limitation, as the presence of a continuous ribbon is one of the main advantages of flexible (“flex”) LED modules.

Document U.S. Pat. No. 8,975,532 B2 shows a solution wherein thermal dissipation may be favoured by means of copper pads on the PCB, which requires a certain width of the Flexible Printed Circuits (FPCs) or strips, with a consequent limitation of the possible application fields.

### SUMMARY

One or more embodiments aim at overcoming the previously outlined limitations.

One or more embodiments relate to a support structure for lighting devices.

One or more embodiments may also concern a corresponding lighting device, as well as a corresponding method.

In one or more embodiments, the problem of providing a satisfying level of thermal dissipation in flexible lighting modules, e.g. so-called “flex” modules, is solved via the application of thermally dissipative elements, so as to preserve the intrinsic advantages of ribbon-like modules which may be cut to length.

One or more embodiments enable to achieve one or more of the following advantages:
higher thermal dissipation capability than standard flexible, e.g. LED, strips/modules, the possibility being given of using thermally dissipative elements integrated as stand-alone components, without the need of providing additional heatsinks (so-called self-cooling capability), and with the option of installation on non-thermally dissipative supports;
possibility of manufacturing continuous modules, e.g. as flexible strips, adapted to be cut to length by final users, the possibility being offered of reducing manufacturing costs while avoiding splicing (another advantage for final users);
possibility of implementing an in-house lamination of thermally dissipative elements, with a consequent increase of the product portfolio, because the same module may be marketed both with and without the provision of thermally dissipative elements;
benefits regarding shipping, stocking and generally handling thanks to the possible use of reel-to-reel technology, while enhancing the thermal dissipation properties of the flexible modules themselves;
possibility of coupling strip-shaped substrates, e.g. adapted to carry power LEDs, to thermally dissipative elements having various sizes and shapes, with the consequent option of further widening the product portfolio by using only a small number of pre-manufactured flexile modules;
possibility of using the thermally dissipative elements in order to implement alternative installation methods, which show a higher efficiency in thermal dissipation than e.g. adhesive tapes; for instance, magnetic inserts may be provided on thermally dissipative elements, so as to enable the fixation on ferromagnetic materials; as an alternative, holes may be present for a fixation via screws;
possibility of using the thermally dissipative elements as supports for lenses or other optical accessories, which may be coupled to the thermally dissipative elements e.g. via screws, mechanical interference or clips.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 exemplifies a general principle on which one or more embodiments may be based,

FIGS. 2 and 3 exemplify, respectively in side elevation and in top view, one or more embodiments,

FIGS. 4 and 5 exemplify, in further top views, one or more embodiments,

FIGS. 6 to 8 exemplify various possible implementations of embodiments, and

FIGS. 9 and 10 exemplify possible implementation criteria of methods according to one or more embodiments.

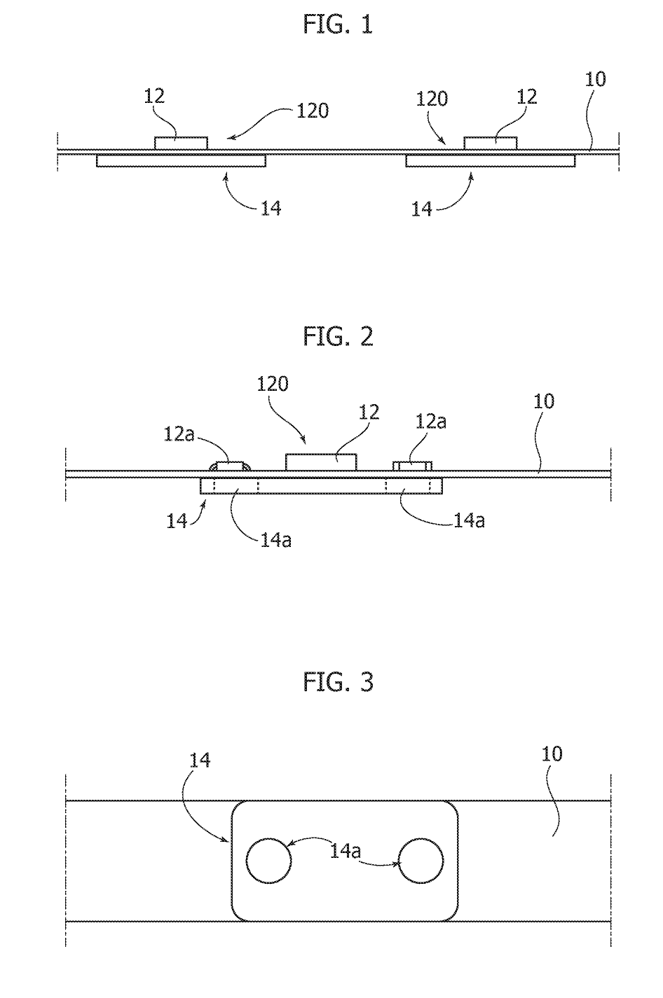

### DETAILED DESCRIPTION

In the following description, numerous specific details are given in order to provide a thorough understanding of various exemplary embodiments. The embodiments may be practiced without one or several of the specific details, or with other methods, components, materials, etc. In other instances, well-known structures, materials, or operations are not shown or described in detail to avoid obscuring the various aspects of the embodiments.

Reference throughout this specification to “one embodiment” or “an embodiment” means that a particular feature, structure, or characteristic described in connection with the embodiment is included in at least one embodiment. Thus, the possible appearances of the phrases “in one embodiment” or “in an embodiment” in various places throughout this specification are not necessarily all referring exactly to the same embodiment. Furthermore, particular features, structures, or characteristics may be combined in any suitable manner in one or more embodiments.

The headings provided herein are given for convenience only, and therefore do not interpret the extent of protection or the scope of the embodiments.

One or more embodiments may envisage the integration of thermally dissipative elements (e.g. of a metal material such as copper), having a plurality of shapes, into a ribbon-like elongate assembly, substantially similar to a Printed Circuit Board (PCB), carrying electrically-powered light radiation sources, such as e.g. solid-state light radiation sources, e.g. LED sources, and/or possible further elements adapted to generate heat in operation: by way of non-limiting example we may mention the drivers/regulating circuits which may be associated to the previously mentioned light radiation sources.
In one or more embodiments, reference 10 denotes a ribbon-like substrate or support, substantially similar to a Flexible Printed Circuit (FPC).

In one or more embodiments, support 10 may include a continuous strip, including at least one electrically insulating layer and at least one electrically conductive layer.

In one or more embodiments, the electrically insulating layer may include e.g. a polymer, such as polyimide or other materials known for this purpose (e.g. polyethylene naphtalate, polyester, FR4).

In one or more embodiments, the electrically conductive layer may take the form of an arrangement or pattern of electrically conductive (e.g. copper) lines, which may be used for supplying (and optionally for controlling e.g. the temperature or the light emission intensity—so-called “dimming”) of electrically-powered light radiation sources, such as solid-state sources e.g. LED sources.

In one or more embodiments such sources, denoted as 12, may be mounted at mounting locations 120 arranged on the front face of substrate 10.

On said substrate (e.g. on the front face or surface thereof) there may optionally be arranged electric/electronic components/circuits 12, for the supply and/or the driving of sources 12, e.g. in order to perform current regulating and/or voltage balancing functions, according to the application needs. Such lighting modules/devices are known in themselves, which makes it unnecessary to provide a more detailed description herein.

One or more embodiments may envisage the coupling, to the presently exemplified support structure, of thermally dissipative elements 14, arranged on the back face o side of substrate 10, i.e. on the side or face opposed the (front) face whereon sources 12 will be placed (together with circuits 12 optionally associated therewith).

In one or more embodiments, thermally dissipative elements 14 may include (or may be comprised of) plates of thermally conductive material, e.g. a metal material such as copper.

In one or more embodiments (and as schematically exemplified in the Figures), said elements may include single elements 14 arranged on the back face of substrate 10 and located opposed the locations 120 on the front face, for mounting sources 12 (and/or the associated circuits 12a, which may be located in the vicinity thereof).

In one or more embodiments (as exemplified in FIG. 3), elements 14 and element 10 may have the same width (in the transverse direction with reference to the lengthwise extension of substrate 10), e.g. in the view of a possible fixation of elements 14 on substrate 10, e.g. via an adhesive tape.

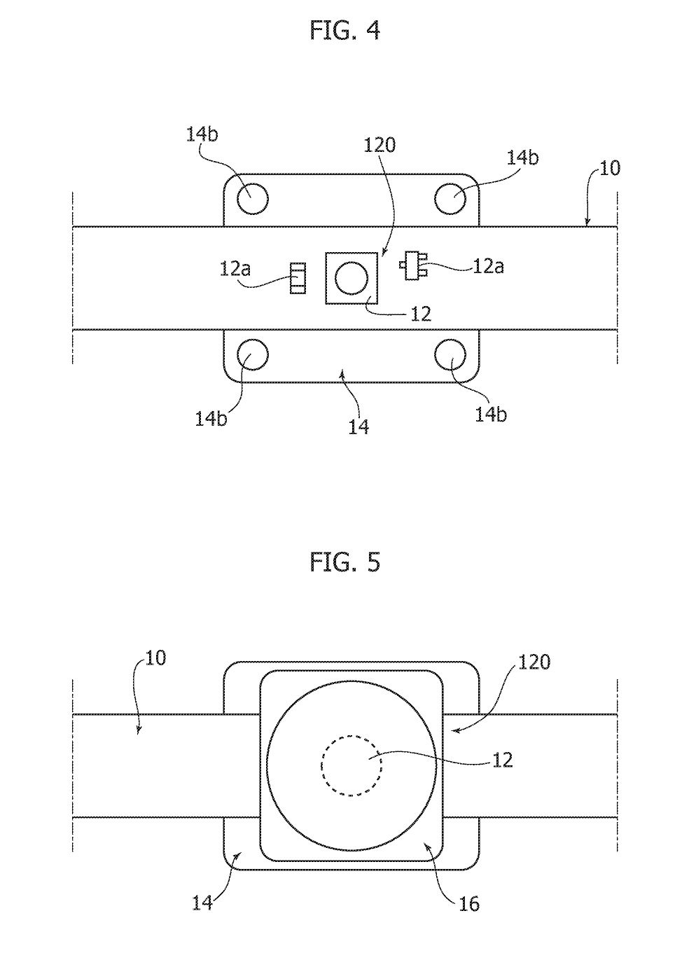

In one or more embodiments, as exemplified e.g. in FIGS. 4 and following, the thermally dissipative elements 14 may have a width (again in the transverse direction with reference to the lengthwise extension of substrate 10) larger than the width of substrate 10.

In one or more embodiments other fixation procedures may be used for the coupling of elements 14 to substrate 10.

For example, FIGS. 2 and 3 exemplify the possibility of providing thermally dissipative elements 14 with one or more magnetic inserts 14a.

In one or more embodiments, such magnetic inserts (or, optionally, the presence of magnetic features not only in the insert or inserts 14a but in the element 14 as a whole) may enable mounting on a magnetically attractable surface and, optionally, may also help retaining element 14 on substrate or support 10 by taking advantage of the ferromagnetic properties of support 10 itself, which are given e.g. by the presence of the electrically conductive layer including the electrically conductive lines for supplying and/or controlling sources 12.

In one or more embodiments (as may be the case of the embodiments exemplified in FIGS. 4 and following, the elements 14 having a larger width than substrate 10), holes 14 may be provided in elements 14, to enable e.g. the fixation of accessories, such as e.g. optical accessories as optical accessories as exemplified in FIGS. 5 to 8.

What previously exemplified is of course representative of only a few possible implementation examples of the embodiments.

In one or more embodiments which are provided with fixation holes (see e.g. holes 14b), substrate 10 may be arranged sandwich-like, optionally clamped, between the thermally dissipative element 14 and a complementary element 16.

In one or more embodiments, said element 16 may include, for example, an optical element such as a lens 16 or a reflector, adapted to be arranged in a position corresponding to the light radiation source 12, so as to perform e.g. a shaping action on the light radiation emitted by the Light Emitting Source (LES) of source 12.

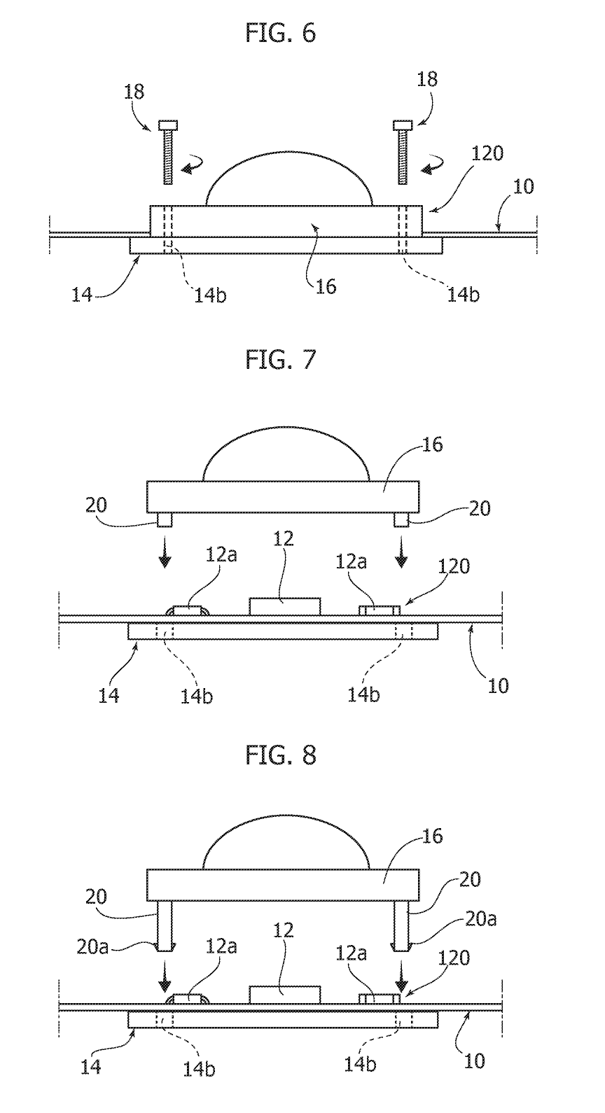

The connection between the thermally dissipative element 14 and the complementary element 16 (e.g. a lens or a reflector), which clamp or enclose substrate 10 sandwich-like therebetween, may be obtained by various means such as, for example:
screws 18 threading within holes 14b (FIG. 6),
pins achieving an interference fit within holes 14b (FIG. 7),
pins 20 having protruding formations (clips) 20a in their distal portion, which may achieve an interference fit within holes 14b (FIG. 8).

In such embodiments, the thermally dissipative element 14 may be wider than substrate 10, the holes 14 being located externally of the edges of substrate 10 (see e.g. FIG. 4), so that said fixation elements (screws 18 or pins 20) may extend within holes 14b sidewise of support 10.

In one or more embodiments, thermally dissipative elements 14 may be coupled to support 10 by lamination.

Such a method (known in itself) may envisage the application, between elements 14 and substrate 10, of an adhesive which is dispensed as a glue or is formed as a layer (adhesive tape).

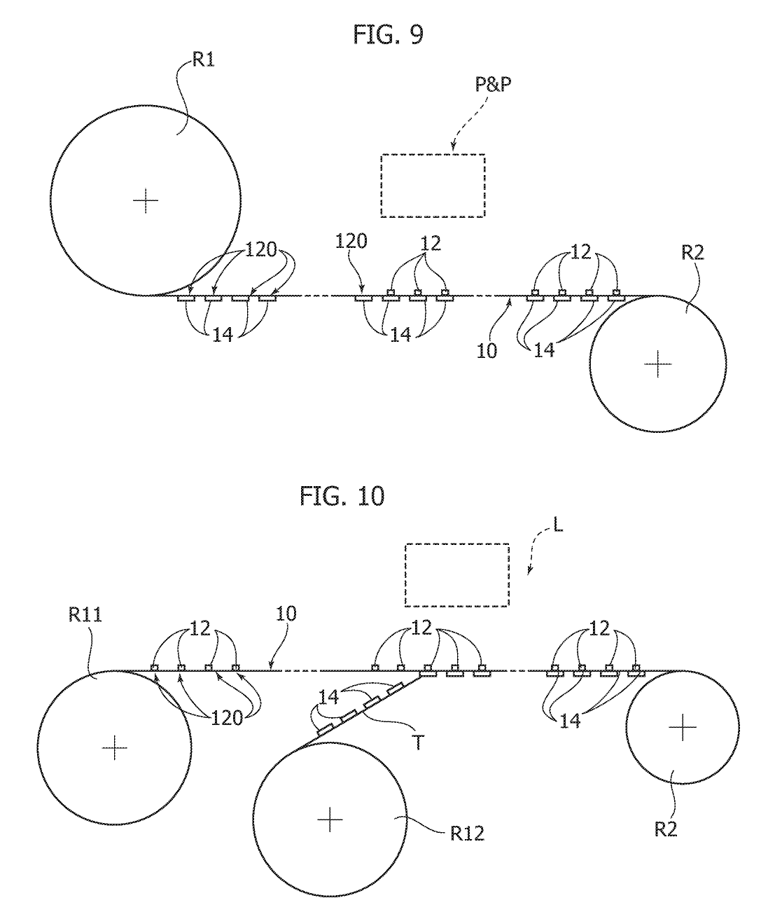

FIG. 9 shows, by way of example, a solution wherein the support structure including substrate 10 with elements 14 applied on the back face is unwound from a ribbon or reel R1, then is fed to a P&P processing station in which (e.g. by means of a Pick & Place procedure) light radiation sources 12 (with optional associated circuits which are not visible in the Figures) are applied on the front face of ribbon 10, in positions corresponding to locations 120.

The subsequent step consists in winding the thus finished lighting device onto an output ribbon or reel R2.

A method as schematically shown in FIG. 9 may be implemented in manufacturing support 10 as a Flexible Printed Circuit (FPC) so as to obtain a so-called panel.

A process as exemplified in FIG. 9 may be implemented in parallel on a plurality of substrates 10, which are unwound from reel R1 as a single sheet and are subsequently separated via a lengthwise cut at the end of the manufacturing process, so as to originate a plurality of LED strips or modules which may be cut to length according to the application needs.

FIG. 10 exemplifies, as an overall similar solution, the possibility of unwinding substrate 10, which is already provided with light radiation sources 12 on the front face, from a reel R11, and feeding it to a lamination station schematically denoted as L.

In station L, thermally dissipative elements 14 may be applied (again according to the previously outlined method) onto the back face of substrate 10, at distances which are set according to the mounting locations 120 of sources 12.

In one or more embodiments, elements 14 may be carried by an auxiliary tape T which is unwound from reel R12.

This enables an in-house coupling operation with a conventional lighting device, available on the market, which includes a substrate 10 having the light radiation sources 12 already mounted on its front face.

As in the case of FIG. 9, the resulting lighting device (i.e. support 10 having the light radiation sources 12 on the front face and the thermally dissipative elements 14 on the back face) may be wound onto an output reel R2.

Also in this instance, the coupling operations of the ribbons unwound from reels R11 and R12 may take place on laminar panels, which are subsequently divided into single strips (or proper modules) via a lengthwise cutting operation, as a final processing step.

One or more embodiments, therefore, may include (e.g. in a lighting device) a support structure for electrically-powered light radiation sources, the structure including a ribbon-like flexible substrate (e.g. 10) the front surface whereof includes mounting locations (e.g. 120) for light radiation sources distributed therealong, the ribbon-like substrate having a back face opposed said front face with a plurality of thermally dissipative elements (e.g. 14) coupled to the back face of the ribbon-like substrate in positions opposed said mounting locations on said front surface.

In one or more embodiments, said thermally dissipative elements may be coupled to the back surface of the ribbon-like substrate by laminating them onto the ribbon-like substrate.

In one or more embodiments, said thermally dissipative elements may be coupled to a mounting surface via at least one means selected out of:
adhesive fixation,
mechanical fixation,
magnetic fixation.

In one or more embodiments, a support structure as exemplified herein may be used in order to obtain a lighting device including, in addition to such a support structure, a plurality of electrically-powered light radiation sources (e.g. 12), preferably solid-state sources such as LED sources, which are arranged at said mounting locations on said front surface.

In one or more embodiments, said lighting device may be implemented in various ways such as, for example:
by providing a support structure as previously exemplified, and arranging (in succession) said light radiation sources on said support structure at said mounting locations on said front surface (see for example the diagram in FIG. 9),

or
by providing said ribbon-like substrate (e.g. 10) having said light radiation sources (already) arranged at said mounting locations on said front surface, and by coupling said thermally dissipative elements to the back surface of the ribbon-like substrate, in said positions opposed said mounting locations on said front surface, with said light radiation sources (already) arranged in the corresponding positions (see e.g. the diagram in FIG. 10).

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A support structure for light radiation sources, comprising a ribbon-like flexible substrate with a front surface having, distributed therealong, mounting locations for electrically-powered light radiation sources, the ribbon-like substrate having a back surface opposed said front surface with a plurality of thermally dissipative elements coupled to the back surface of the ribbon-like substrate at locations opposed said mounting locations on said front surface.

2. The support structure of claim 1, wherein said thermally dissipative elements include metal material.

3. The support structure of claim 1, wherein the ribbon-like substrate has a width across its length and said thermally dissipative elements have a width equal to the width of the ribbon-like substrate.

4. The support structure of claim 1, wherein the ribbon-like substrate has a width across its length and said thermally dissipative elements have a width larger than the width of the ribbon-like substrate.

5. The support structure of claim 1, wherein said thermally dissipative elements include at least one magnetic portion.

6. The support structure of claim 1, wherein said thermally dissipative elements are coupled to the back surface of said ribbon-like substrate by lamination to the ribbon-like substrate.

7. The support structure of claim 1, wherein said thermally dissipative elements are coupleable to a mounting surface by at least:
adhesive fixation,
mechanical fixation,
magnetic fixation.

8. The support structure of claim 1, wherein said thermally dissipative elements are coupled to the back surface of said ribbon-like substrate with said thermally dissipative elements cooperating with a complementary element with the ribbon-like substrate sandwiched between the thermally dissipative element and the complementary element.

9. A lighting device, comprising:
a support structure, the support structure comprising a ribbon-like flexible substrate with a front surface having, distributed therealong, mounting locations for electrically-powered light radiation sources, the ribbon-like substrate having a back surface opposed said front surface with a plurality of thermally dissipative elements coupled to the back surface of the ribbon-like substrate at locations opposed said mounting locations on said front surface,
and
a plurality of electrically-powered light radiation sources, arranged at said mounting locations on said front surface.

10. A method of providing a lighting device,
the lighting device, comprising:
a support structure, the support structure comprising a ribbon-like flexible substrate with a front surface having, distributed therealong, mounting locations for electrically-powered light radiation sources, the ribbon-like substrate having a back surface opposed said front surface with a plurality of thermally dissipative elements coupled to the back surface of the ribbon-like substrate at locations opposed said mounting locations on said front surface, and
a plurality of electrically-powered light radiation sources, arranged at said mounting locations on said front surface,
the method comprising :
providing the support structure and arranging said light radiation sources on said support structure at said mounting locations on said front surface, or
providing said ribbon-like substrate with said light radiation sources arranged at said mounting locations on said front surface, and coupling said thermally dissipative elements to the back surface del ribbon-like substrate at said locations opposed said mounting locations on said front surface with said light radiation sources arranged thereat.
